(19) United States
(12) Patent Application Publication
(10) Pub. No.: US 2025/0089416 A1
(43) Pub. Date: Mar. 13, 2025

(54) Display Panel

(71) Applicant: Alps Alpine Co., Ltd., Tokyo (JP)

(72) Inventor: Kiyotaka AIZAWA, Miyagi-ken (JP)

(21) Appl. No.: 18/956,237

(22) Filed: Nov. 22, 2024

Related U.S. Application Data
(63) Continuation of application No. PCT/JP2023/008118, filed on Mar. 3, 2023.

(30) Foreign Application Priority Data
Jun. 23, 2022 (JP) 2022-101374

(51) Int. Cl. H01L 33/58; B32B 7/12; B32B 27/06; H01L 25/075

(52) U.S. Cl. CPC H10H 20/855; B32B 7/12; B32B 27/06; B32B 2250/44; B32B 2307/4023; B32B 2307/41; B32B 2307/412; B32B 2457/20; H01L 25/0753

(57) ABSTRACT

A display panel for displaying a predetermined design shape on a display surface when a light source emits light includes a decorative sheet including, on a transparent base material, stacked in sequence, a light-transmissive printed layer provided in an area, a light-shielding printed layer having an opening of the predetermined design shape, and an adhesive layer, and a transparent adherend to which the decorative sheet is attached with the adhesive layer. In plan view, a portion of an outer edge of the light-transmissive printed layer reaches an outer edge of the base material.

### CLAIM OF PRIORITY

This application is a Continuation of International Application No. PCT/JP2023/008118 filed on Mar. 3, 2023, which claims benefit of Japanese Patent Application No. 2022-101374 filed on Jun. 23, 2022. The entire contents of each application noted above are hereby incorporated by reference.

### BACKGROUND OF THE INVENTION

### 1. Field of the Invention

The present invention relates to a display panel.

### 2. Description of the Related Art

Japanese Unexamined Patent Application Publication No. 2017-061586 relates to an adhesive sheet including an adhesive layer and discloses a technique for discharging air bubbles trapped in the attachment of the adhesive sheet to an adherend, by using channels for discharging air bubbles provided to an adhesive layer.

However, these channels for discharging air bubbles provided to the adhesive layer may lower the light-transmissive property of the adhesive. Accordingly, if such an adhesive layer is applied to a display panel and light passes through it, the luminance of a design shape displayed on the display surface of the display panel may decrease.

### SUMMARY OF THE INVENTION

A display panel according to an aspect is a display panel for displaying a predetermined design shape on a display surface when a light source emits light. The display panel includes a decorative sheet including, on a transparent base material, stacked in sequence, a light-transmissive printed layer provided in an area, a light-shielding printed layer having an opening of the predetermined design shape, and an adhesive layer, and a transparent adherend to which the decorative sheet is attached with the adhesive layer. In plan view, a portion of an outer edge of the light-transmissive printed layer reaches an outer edge of the base material.

A display panel according to an aspect can readily discharge air bubbles trapped when a decorative sheet is attached to an adherend to the outside without a reduction in the luminance of a design shape displayed on a display surface of the display panel.

### BRIEF DESCRIPTION OF THE DRAWINGS

FIG. 1 is a cross-sectional view schematically illustrating a stacked structure of a display panel according to an embodiment;

FIG. 2 is a plan view illustrating a first embodiment of a shape of a light-transmissive printed layer in a display panel according to an embodiment;

FIG. 3 is a plan view illustrating a second embodiment of a shape of a light-transmissive printed layer in a display panel according to an embodiment; and

FIG. 4 is a plan view illustrating a third embodiment of a shape of a light-transmissive printed layer in a display panel according to an embodiment.

### DESCRIPTION OF THE PREFERRED EMBODIMENTS

Hereinafter, embodiments will be described with reference to the attached drawings. It should be noted that the drawings are partially emphasized or modified for ease of understanding, and the relative dimensional relationships are not accurately depicted.

### Structure of Display Panel 100

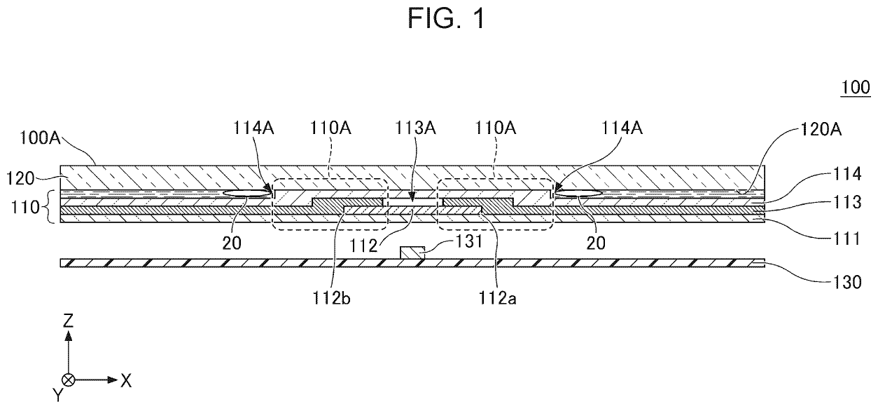

FIG. 1 is a cross-sectional view schematically illustrating a stacked structure of a display panel 100 according to an embodiment.

In the following description, for convenience, the X-axis direction denotes the left-right direction, the Y-axis direction denotes the front-rear direction, and the Z-axis direction denotes the up-down direction, in which, the X-axis positive direction denotes the rightward direction, the Y-axis positive direction denotes the forward direction, and the Z-axis positive direction denotes the upward direction. It should be noted that these directions denote relative positional relationships in a device and do not limit device installation directions or operation directions, and similar relative positional relationships in the device may have different installation directions or operation directions and those are all included within the scope of the invention.

As illustrated in FIG. 1, the display panel 100 includes a decorative sheet 110, a transparent panel 120, a substrate 130, and a light-emitting diode (LED) 131 (an example of “light source”). The display panel 100 can display a predetermined design shape (for example, a character, a symbol, a graphic, or the like) on a display surface 100A when the LED 131 emits light.

The decorative sheet 110 has a multi-layered structure, and is a sheet member. The decorative sheet 110 is attached to a rear surface 120A of the transparent panel 120 to decorate the display panel 100. The decorative sheet 110 includes, in sequence from the rear surface side (from the bottom side in the drawing), a base material 111, a light-transmissive printed layer 112, a light-shielding printed layer 113, and an adhesive layer 114.

The base material 111 is a flexible, transparent sheet member having the same external shape as the decorative sheet 110 and serves as a base of the decorative sheet 110. More specifically, the decorative sheet 110 is formed by stacking, on a top surface of the base material 111, the other layers (the light-transmissive printed layer 112, the light-shielding printed layer 113, and the adhesive layer 114) in sequence. For example, the base material 111 is formed by using a flexible transparent sheet material (for example, polymethyl methacrylate (PMMA), polycarbonate (PC), urethane, ABS, glass, or the like).

The light-transmissive printed layer 112 is formed, on the surface of the base material 111, in an area overlapping predetermined design shapes to be displayed on the display surface 100A (i.e., an area overlapping openings 113A in the light-shielding printed layer 113, which will be described below) to be larger than the design shapes so as to always overlap the area even if the positions and sizes vary. The light-transmissive printed layer 112 has a light-transmissive property and has a specific effect on the light that passes through the light-transmissive printed layer 112. For example, the light-transmissive printed layer 112 is formed by using a white ink having a light-transmissive property. This enables the light-transmissive printed layer 112 to display the predetermined design shapes in white on the display surface 100A such that an internal structure of the display panel 100 is not visible from the outside through the openings 113A in the light-shielding printed layer 113. In addition, the light-transmissive printed layer 112 enables the LED 131 to emit light uniformly in an emission color of the LED 131. In this embodiment, as an example of the light-transmissive printed layer 112, a white printed layer formed by silk screen printing is used.

The light-shielding printed layer 113 is formed in the same external shape as the base material 111, and is formed on a surface of the light-transmissive printed layer 112. The light-shielding printed layer 113 has a light-shielding property and has the openings 113A each having a predetermined design shape to be displayed on the display surface 100A of the display panel 100. The light-shielding printed layer 113 is formed on the entire surface of the base material 111 except the openings 113A such that the internal structure of the display panel 100 is not visible from the outside in areas other than the openings 113A. The light-shielding printed layer 113 allows light, which is emitted from the LED 131 and passes through the base material 111 and the light-transmissive printed layer 112, to partially pass through with the openings 113A, thereby displaying the optical images of the predetermined design shapes on the display surface 100A of the display panel 100. For example, the light-shielding printed layer 113 is formed, on the surface of the base material 111 on which the light-transmissive printed layer 112 is formed, by printing predetermined design shapes by using a light-shielding black ink. Accordingly, the light-shielding printed layer 113 is formed in a state in which the portion not overlapping the light-transmissive printed layer 112 is in contact with the surface of the base material 111, and the portion overlapping the light-transmissive printed layer 112 is in contact with the surface of the light-transmissive printed layer 112. In this embodiment, as an example of the light-shielding printed layer 113, a black printed layer formed by silk screen printing is used.

The adhesive layer 114 has an adhesive property and a light-transmissive property and is formed in the same external shape as the base material 111 and the light-shielding printed layer 113. The adhesive layer 114 is formed over the entire area of the base material 111 and on the entire surface of the light-shielding printed layer 113. It should be noted that, in this embodiment, as an example of the adhesive layer 114, a double-sided tape that has a light-transmissive property is used.

The transparent panel 120 is a member including a transparent resin and has a plate-like shape. The transparent panel 120 is an example of an “adherend”. The decorative sheet 110 is attached to the rear surface 120A with the adhesive layer 114 of the decorative sheet 110.

The substrate 130 is a member including resin and has a plate-like shape. The substrate 130 is provided below the decorative sheet 110 and separated from the decorative sheet 110. The substrate 130 may be, for example, a printed wired board (PWB).

The LED 131 is, on a top surface of the substrate 130 (i.e., on a rear side of the base material 111), mounted at a position overlapping the predetermined design shapes to be displayed on the display surface 100A of the display panel 100. The LED 131 emits light at a predetermined timing and illuminates the openings 113A in the light-shielding printed layer 113 with light of a predetermined color from the rear surface side of the decorative sheet 110. The light emission timing of the LED 131 is externally controlled.

The display panel 100 having the above-described structure can display the predetermined design shapes on the display surface 100A by allowing the light emitted from the LED 131 to pass through the base material 111, the light-transmissive printed layer 112, the openings 113A in the light-shielding printed layer 113, the adhesive layer 114, and the transparent panel 120.

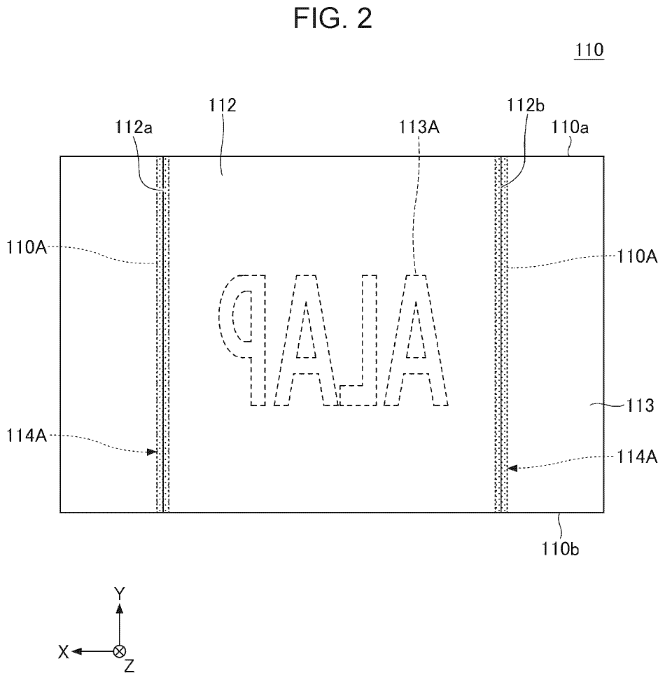

As illustrated in FIG. 1, the decorative sheet 110 has a thick portion 110A that is relatively thicker than an outer area. The thick portion 110A is formed by stacking the light-shielding printed layer 113 and the adhesive layer 114 on a side 112a and a side 112b (an example of an “outer edge of a light-transmissive printed layer”), which are portions of an outer edge of the light-transmissive printed layer 112. The thick portion 110A is, in plan view, formed along the side 112a and the side 112b of the light-transmissive printed layer 112 (see FIG. 2 described below). Accordingly, the decorative sheet 110 has, at the adhesive layer 114, a step portion 114A between the thick portion 110A and an area outside the thick portion 110A. As a result, in the display panel 100, when the decorative sheet 110 is attached to the rear surface 120A of the transparent panel 120, as illustrated in FIG. 1, air bubbles 20 may be trapped between the transparent panel 120 and the decorative sheet 110 (the surface of the area outside the thick portion 110A) and in a space in the vicinity of the above-described step portion 114A.

It should be noted that since FIG. 1 is a schematic view, a parallel gap extends on the left and right (X-axis directions) of the air bubbles 20. However, when the decorative sheet 110 is actually attached, the decorative sheet 110 bends outside the step portion 114A and contacts and adheres to the transparent panel 120 and there is no gap (space) in the outside area away in the left and right (X-axis directions) from the space in which the air bubbles 20 are illustrated. Accordingly, in the areas other than the space in which the air bubbles 20 are illustrated, the adhesive layer 114 and the transparent panel 120 are in contact with each other.

### First Embodiment of Shape of Light-Transmissive Printed Layer 112

FIG. 2 is a plan view of the decorative sheet 110 illustrating a first embodiment of the shape of the light-transmissive printed layer 112 in the display panel 100 according to an embodiment. It should be noted that in FIG. 2, the base material 111 and the adhesive layer 114 are omitted; however, the external shapes of the base material 111 and the adhesive layer 114 are the same rectangular shape as the light-shielding printed layer 113.

As illustrated in FIG. 2, the decorative sheet 110 according to the first embodiment is rectangular with the left-right direction (X-axis direction) as the longitudinal direction in plan view from below (Z-axis negative direction).

In the example in FIG. 2, the light-transmissive printed layer 112 is formed, in plan view from below (Z-axis negative direction), in a center of the decorative sheet 110 and at a position overlapping the openings 113A (as an example, each character of “ALAP”) formed in the light-shielding printed layer 113. In addition, the light-transmissive printed layer 112 has, in plan view from below (Z-axis negative direction), a rectangular shape covering the entire of the openings 113A. The light-transmissive printed layer 112 is formed in an area of the base material 111 and the light-shielding printed layer 113 and overlaps the entire of the openings 113A.

Here, in the example illustrated in FIG. 2, the width of the light-transmissive printed layer 112 in the left-right direction (X-axis direction) is less than those of the base material 111 and the light-shielding printed layer 113 in the left-right direction (X-axis direction). On the other hand, the width of the light-transmissive printed layer 112 in the front-rear direction (Y-axis direction) is equal to those of the base material 111 and the light-shielding printed layer 113 in the front-rear direction (Y-axis direction).

Accordingly, in the decorative sheet 110 according to the first embodiment, each of the side 112a on the right side (X-axis positive side) and the side 112b on the left side (X-axis negative side) of the outer edge of the light-transmissive printed layer 112 reaches each of a side 110a on the front side (Y-axis positive side) and a side 110b (Y-axis negative side) on the rear side of the outer edge of the decorative sheet 110 (an example of an “outer edge of a base material”).

Accordingly, in the decorative sheet 110 according to the first embodiment, each of the thick portion 110A and the step portion 114A formed along the side 112a on the right side (X-axis positive side) of the light-transmissive printed layer 112 and the thick portion 110A and the step portion 114A formed along the side 112b on the left side (X-axis negative side) of the light-transmissive printed layer 112 reaches each of the side 110a on the front side (Y-axis positive side) and the side 110b on the rear side (Y-axis negative side) of the outer edge (outer edge of the base material 111) of the decorative sheet 110.

With this structure, when the decorative sheet 110 is attached to the rear surface 120A of the transparent panel 120, even if air is trapped between the transparent panel 120 and the decorative sheet 110 (the step portion 114A in the vicinity of the thick portion 110A) and air bubbles 20 are generated, the display panel 100 according to the first embodiment can press the air bubbles 20 out along the side 112a on the right side (X-axis positive side) or the side 112b on the left side (X-axis negative side) of the light-transmissive printed layer 112 from the center to the front (Y-axis positive direction) or the rear (Y-axis negative direction) in the front-rear directions (Y-axis directions) in the step portion 114A, discharging the air bubbles 20 from the side 110a on the front side (Y-axis positive side) or the side 110b on the rear side (Y-axis negative direction) of the decorative sheet 110.

Accordingly, when the decorative sheet 110 is attached to the rear surface 120A of the transparent panel 120, the display panel 100 according to the first embodiment can readily discharge the air bubbles 20 generated between the transparent panel 120 and the decorative sheet 110, for example, by sequentially applying pressing force by using silicone or the like having an inclined pressing surface from the center to the outside in the front-rear directions (Y-axis directions).

### Second Embodiment of Shape of Light-Transmissive Printed Layer 112

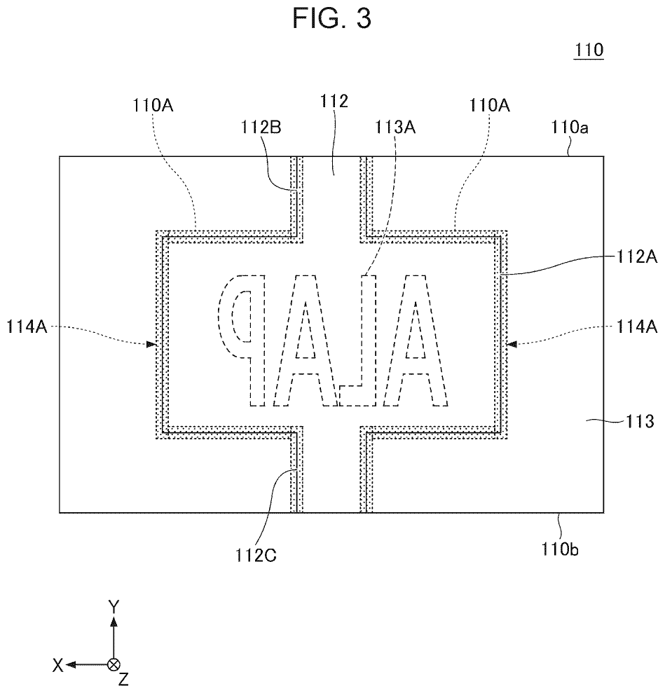

FIG. 3 is a plan view of the decorative sheet 110 illustrating a second embodiment of the shape of the light-transmissive printed layer 112 in the display panel 100 according to an embodiment. It should be noted that in FIG. 3, the base material 111 and the adhesive layer 114 are omitted; however, the external shapes of the base material 111 and the adhesive layer 114 are the same rectangular shape as the light-shielding printed layer 113. In the following description, to components the same as or similar to those in the first embodiment, the same reference names and numerals are given and their descriptions may be omitted.

As illustrated in FIG. 3, the decorative sheet 110 according to the second embodiment is rectangular with the left-right direction (X-axis direction) as the longitudinal direction in plan view from below (Z-axis negative direction). In the example in FIG. 3, the light-transmissive printed layer 112 has, in plan view from below (Z-axis negative direction), in a center of the decorative sheet 110 and at a position overlapping the openings 113A formed in the light-shielding printed layer 113, a rectangular main section 112A that covers the entire of the openings 113A. The main section 112A is formed in an area of the base material 111 and the light-shielding printed layer 113 and covers the entire of the openings 113A.

Here, in the example illustrated in FIG. 3, the width of the main section 112A of the light-transmissive printed layer 112 in the left-right direction (X-axis direction) is less than that of the decorative sheet 110 in the left-right direction (X-axis direction). The width of the main section 112A of the light-transmissive printed layer 112 in the front-rear direction (Y-axis direction) is less than that of the decorative sheet 110 in the front-rear direction (Y-axis direction).

In the example illustrated in FIG. 3, in plan view from below (Z-axis negative direction), the light-transmissive printed layer 112 has a first connection portion 112B that has a certain width (a width less than that of the main section 112A) from a central portion of a side of the main section 112A on the front side (Y-axis positive side) toward the front (Y-axis positive direction) and extends linearly. The first connection portion 112B reaches the side 110a on the front side (Y-axis positive side) of the outer edge of the decorative sheet 110. Accordingly, in the display panel 100 according to the second embodiment, the thick portion 110A and the step portion 114A formed along the first connection portion 112B reach the side 110a on the front side (Y-axis positive side) of the outer edge of the decorative sheet 110.

In the example illustrated in FIG. 3, in plan view from below (Z-axis negative direction), the light-transmissive printed layer 112 has a second connection portion 112C that has a certain width (a width less than that of the main section 112A) from a central portion of a side of the main section 112A on the rear side (Y-axis negative side) toward the rear (Y-axis negative direction) and extends linearly. The second connection portion 112C reaches the side 110b on the rear side (Y-axis negative side) of the outer edge of the decorative sheet 110. Accordingly, in the display panel 100 according to the second embodiment, the thick portion 110A and the step portion 114A formed along the second connection portion 112C reach the side 110b on the rear side (Y-axis negative side) of the outer edge of the decorative sheet 110.

With this structure, when the decorative sheet 110 is attached to the rear surface 120A of the transparent panel 120, even if air is trapped between the transparent panel 120 and the decorative sheet 110 (the step portion 114A in the vicinity of the thick portion 110A) and air bubbles 20 are generated, the display panel 100 according to the second embodiment can press the air bubbles 20 out along the first connection portion 112B or the second connection portion 112C of the light-transmissive printed layer 112 to the front (Y-axis positive direction) or the rear (Y-axis negative direction) in the step portion 114A, discharging the air bubbles 20 from the side 110a on the front side (Y-axis positive side) or the side 110b on the rear side (Y-axis negative side) of the decorative sheet 110.

Accordingly, when the decorative sheet 110 is attached to the rear surface 120A of the transparent panel 120, the display panel 100 according to the second embodiment can readily discharge the air bubbles 20 generated between the transparent panel 120 and the decorative sheet 110, for example, by sequentially applying pressing force by using a silicone or the like having an inclined pressing surface from the center to the outside in the front-rear directions (Y-axis directions).

### Third Embodiment of Shape of Light-Transmissive Printed Layer 112

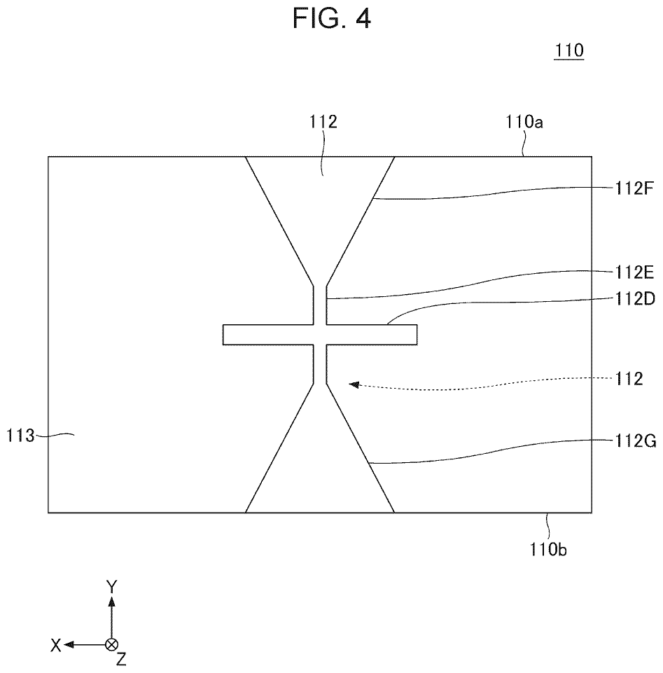

FIG. 4 is a plan view of the decorative sheet 110 illustrating a third embodiment of the shape of the light-transmissive printed layer 112 in the display panel 100 according to an embodiment. In the first embodiment and the second embodiment, the light-transmissive printed layer 112 is provided to overlap the openings 113A formed in the light-shielding printed layer 113, and the predetermined design shapes are displayed on the display surface 100A with the light passing through the light-transmissive printed layer 112. In the third embodiment, a case in which the light-transmissive printed layer 112 is used for positioning the decorative sheet 110 with respect to the transparent panel 120 will be described.

Although not illustrated in FIG. 4, the decorative sheet 110 according to the third embodiment has, continuously in the X direction, the structure of the decorative sheet 110 according to the first embodiment or the second embodiment (i.e., the structure for displaying predetermined design shapes on the display surface 100A).

In FIG. 4, although the base material 111 and the adhesive layer 114 are not illustrated, similarly to the first embodiment and the second embodiment, the base material 111 has the same external shape as the decorative sheet 110, the adhesive layer 114 is formed over the entire area of the base material 111, and the light-shielding printed layer 113 is formed on the entire surface of the base material 111 except the openings 113A. In the following description, to components the same as or similar to those in the first embodiment and the second embodiment, the same reference names and numerals are given and their descriptions may be omitted.

As illustrated in FIG. 4, the decorative sheet 110 according to the third embodiment is rectangular with the left-right direction (X-axis direction) as the longitudinal direction in plan view from below (Z-axis negative direction).

In the example in FIG. 4, the light-transmissive printed layer 112 is formed, in plan view from below (Z-axis negative direction), at a position not overlapping the openings 113A formed in the light-shielding printed layer 113 (i.e., a position not overlapping the predetermined design shapes). Accordingly, the light-transmissive printed layer 112 illustrated in FIG. 4 cannot be visually recognized from the front surface side of the decorative sheet 110 and can be visually recognized only from the rear surface side of the decorative sheet 110.

In addition, in the example illustrated in FIG. 4, the light-transmissive printed layer 112 has a first straight line portion 112D and a second straight line portion 112E. The first straight line portion 112D is, in plan view from above, provided at a center of the decorative sheet 110 and extends linearly in the left-right direction (X-axis direction). The second straight line portion 112E is, in plan view from above, provided at a center of the decorative sheet 110 and extends linearly in the front-rear direction (Y-axis direction). In plan view from below, the first straight line portion 112D and the second straight line portion 112E have a cross shape that is orthogonal to each other at each midpoint. The first straight line portion 112D and the second straight line portion 112E function as a “marker” having a positioning shape (in this embodiment, the cross shape) for positioning the decorative sheet 110 with respect to the transparent panel 120.

In the example illustrated in FIG. 4, in plan view from below (Z-axis negative direction), the light-transmissive printed layer 112 has a first connection portion 112F that extends from an end of the second straight line portion 112E on the front side (Y-axis positive side) toward the front (Y-axis positive direction). The first connection portion 112F reaches the side 110a on the front side (Y-axis positive side) of the outer edge of the decorative sheet 110. Accordingly, in the decorative sheet 110 according to the third embodiment, the thick portion 110A and the step portion 114A formed along the first connection portion 112F reach the side 110a on the front side (Y-axis positive side) of the outer edge of the decorative sheet 110.

In the example illustrated in FIG. 4, in plan view from below (Z-axis negative direction), the light-transmissive printed layer 112 has a second connection portion 112G that extends from an end of the second straight line portion 112E on the rear side (Y-axis negative side) toward the rear (Y-axis negative direction). The second connection portion 112G reaches the side 110b on the rear side (Y-axis negative side) of the outer edge of the decorative sheet 110. Accordingly, in the decorative sheet 110 according to the third embodiment, the thick portion 110A and the step portion 114A formed along the second connection portion 112G reach the side 110b on the rear side (Y-axis negative side) of the outer edge of the decorative sheet 110.

With this structure, when the decorative sheet 110 is attached to the rear surface 120A of the transparent panel 120, even if air is trapped between the transparent panel 120 and the decorative sheet 110 (the step portion 114A in the vicinity of the thick portion 110A) and air bubbles 20 are generated, the display panel 100 according to the third embodiment can press the air bubbles 20 out along the first connection portion 112F or the second connection portion 112G of the light-transmissive printed layer 112 to the front (Y-axis positive direction) or the rear (Y-axis negative direction) in the step portion 114A, discharging the air bubbles 20 from the side 110a on the front side (Y-axis positive side) or the side 110b on the rear side (Y-axis negative side) of the decorative sheet 110.

Accordingly, when the decorative sheet 110 is attached to the rear surface 120A of the transparent panel 120, the display panel 100 according to the third embodiment can readily discharge the air bubbles 20 generated between the transparent panel 120 and the decorative sheet 110, for example, by sequentially applying pressing force by using a silicone or the like having an inclined pressing surface from the center to the outside in the front-rear directions (Y-axis directions).

In particular, in the example illustrated in FIG. 4, the first connection portion 112F and the second connection portion 112G of the light-transmissive printed layer 112 have a tapered shape with the left-right width (width in the X-axis direction) gradually increased toward the outer edge of the decorative sheet 110.

With this structure, while maintaining the narrow lines as in the second straight line portion 112E as the function of the marker, the display panel 100 according to the third embodiment has the portions having gradually increasing widths, which do not have the function of the marker. Accordingly, the left and right step portions can be prevented from connecting to each other due to the narrow lines, and the difficulty in discharging the air bubbles 20 can be reduced.

It should be noted that in the first to third embodiments, in plan view, the decorative sheet 110 has the rectangular shape with the front-rear direction (Y-axis direction) as the short-side direction and the left-right direction (X-axis direction) as the long-side direction, and the light-transmissive printed layer 112 is extended in the short-side direction (Y-axis direction) to enable the light-transmissive printed layer 112 to reach the outer edge. The display panel 100 according to the first to third embodiments enables the light-transmissive printed layer 112 to reach the closest outer edge, reducing the amount of use of ink for the light-transmissive printed layer 112.

### Operations and Effects of Display Panel 100

As described above, the display panel 100 according to one embodiment is the display panel 100 for displaying predetermined design shapes on the display surface 100A when the LED 131 emits light. The display panel 100 includes, the decorative sheet 110 that includes, on the transparent base material 111, stacked in sequence, the light-transmissive printed layer 112 provided in an area, the light-shielding printed layer 113 having the openings 113A of the predetermined design shapes, and the adhesive layer 114, and the transparent panel 120 to which the decorative sheet 110 is attached with the adhesive layer 114. In plan view, a portion of an outer edge of the light-transmissive printed layer 112 reaches an outer edge of the base material 111.

This structure enables the display panel 100 according to one embodiment, without using anti-bubble equipment such as vacuum equipment, to discharge air bubbles 20, which are trapped between the adhesive layer 114 and the transparent panel 120 when the decorative sheet 110 is attached, to the outside along the outer edge of the light-transmissive printed layer 112. In addition, since it is not necessary to provide an air bubble discharging flow channel to the adhesive layer 114 in the display panel 100 according to one embodiment, the light-transmissive property of the adhesive layer 114 does not decrease.

Accordingly, the display panel 100 according to one embodiment can readily discharge air bubbles 20, which are trapped when the decorative sheet 110 is attached to the transparent panel 120, to the outside without reducing the luminance of the design shape displayed on the display surface 100A.

In addition, the display panel 100 according to one embodiment includes the light-transmissive printed layer 112 provided in an area of the base material 111, reducing the amount of ink used for the light-transmissive printed layer 112 compared with a case in which the light-transmissive printed layer 112 is provided in the entire area of the base material 111.

The display panel 100 according to one embodiment may have, in plan view, along the outer edge of the light-transmissive printed layer 112, the thick portion 110A at the adhesive layer 114, which is formed by stacking the light-shielding printed layer 113 and the adhesive layer 114 on the outer edge of the light-transmissive printed layer 112, and the step portion 114A formed between the thick portion 110A and the area outside the thick portion 110A. The step portion 114A reaches, along the outer edge of the light-transmissive printed layer 112, the outer edge of the base material 111.

This structure enables the display panel 100 according to one embodiment to discharge air bubbles 20, which are trapped between the adhesive layer 114 and the transparent panel 120 when the decorative sheet 110 is attached, to the outside through the inside of the step portion 114A of the adhesive layer 114 formed along the outer edge of the light-transmissive printed layer 112.

The display panel 100 according to one embodiment may include the LED 131 disposed on the rear side of the base material 111. The light-transmissive printed layer 112 is provided, on the base material 111, in an area overlapping the predetermined design shape, and the predetermined design shapes are displayed on the display surface 100A by allowing light emitted from the LED 131 to pass through the base material 111, the light-transmissive printed layer 112, the openings 113A in the light-shielding printed layer 113, the adhesive layer 114, and the transparent panel 120.

This structure enables the display panel 100 according to one embodiment to display the predetermined design shapes formed through the openings 113A of the light-shielding printed layer 113 on the display surface 100A.

In the display panel 100 according to one embodiment, the light-transmissive printed layer 112 may include the main section 112A provided at a position overlapping the predetermined design shapes and the connection portions 112B and 112C connecting the main section 112A and the outer edge of the base material 111.

This structure enables the display panel 100 according to one embodiment to readily discharge air bubbles 20, which are trapped in the step portion 114A of the main section 112A when the decorative sheet 110 is attached, to the outside through the step portions 114A of the connection portions 112B and 112C. In addition, this structure enables the display panel 100 according to one embodiment to have the minimized main section 112A, reducing the amount of ink used for the light-transmissive printed layer 112.

In the display panel 100 according to one embodiment, the light-transmissive printed layer 112 may include the marker portion provided, on the base material 111, in an area not overlapping the predetermined design shapes, the marker portion having a predetermined positioning shape, and the connection portions 112F and 112G connecting the marker portion and the outer edge of the base material 111.

This structure enables the display panel 100 according to one embodiment to readily discharge air bubbles 20, which are trapped in the step portion 114A of the marker portion when the decorative sheet 110 is attached, to the outside through the edge portions of the connection portions 112F and 112G.

In the display panel 100 according to one embodiment, the connection portions 112F and 112G may have, in plan view, a shape that gradually widens from the marker portion toward the outer edge of the base material 111.

With this structure, in the display panel 100 according to one embodiment, the left and right step portions of the narrow marker portion can be prevented from connecting to each other, and the difficulty in discharging the air bubbles 20 can be reduced.

In the display panel 100 according to one embodiment, the adhesive layer 114 may be a double-sided tape having a light-transmissive property.

Accordingly, the display panel 100 according to one embodiment does not require a specialized anti-bubble double-sided tape with a low light-transmissive property, and thus a less expensive double-sided tape with a higher light-transmissive property can be used.

In the display panel 100 according to one embodiment, the light-transmissive printed layer 112 may be a white printed layer formed by silk screen printing.

This structure enables the display panel 100 according to one embodiment to have the thick light-transmissive printed layer 112 compared with a case in which the light-transmissive printed layer 112 is formed by other printing methods such as offset printing and to have the larger step portion 114A. Accordingly, air bubbles 20 can be readily discharged.

In the display panel 100 according to one embodiment, the light-shielding printed layer 113 may be a black printed layer formed by silk screen printing.

This structure enables the display panel 100 according to one embodiment to have the thick light-shielding printed layer 113 compared with a case in which the light-shielding printed layer 113 is formed by other printing methods such as offset printing and to have the larger step portion 114A. Accordingly, air bubbles 20 can be readily discharged.

While the embodiments of the present invention have been described in detail, it is to be understood that the invention is not limited to these embodiments, various modifications or changes may be made within the scope of the invention described in the claims.

What is claimed is:

1. A display panel for displaying a predetermined design shape on a display surface when a light source emits light, the display panel comprising:
a decorative sheet including, on a transparent base material, stacked in sequence, a light-transmissive printed layer provided in an area, a light-shielding printed layer having an opening of the predetermined design shape, and an adhesive layer; and
a transparent adherend to which the decorative sheet is attached with the adhesive layer, wherein
in plan view, a portion of an outer edge of the light-transmissive printed layer reaches an outer edge of the base material.

2. The display panel according to claim 1, wherein the display panel has,
in plan view, along the outer edge of the light-transmissive printed layer, a thick portion formed by stacking the light-shielding printed layer and the adhesive layer on the outer edge of the light-transmissive printed layer; and
at the adhesive layer, a step portion formed between the thick portion and an area outside the thick portion, wherein
the step portion reaches, along the outer edge of the light-transmissive printed layer, the outer edge of the base material.

3. The display panel according to claim 1, further comprising:
a light source disposed on a rear side of the base material, wherein
the light-transmissive printed layer is provided, on the base material, in an area overlapping the predetermined design shape, and
the predetermined design shape is displayed on the display surface by allowing light emitted from the light source to pass through the base material, the light-transmissive printed layer, the opening in the light-shielding printed layer, the adhesive layer, and the adherend.

4. The display panel according to claim 3, wherein the light-transmissive printed layer comprises
a main section provided at a position overlapping the predetermined design shape; and
a connection portion connecting the main section and the outer edge of the base material.

5. The display panel according to claim 1, wherein the light-transmissive printed layer comprises
a marker portion provided, on the base material, in an area not overlapping the predetermined design shape, the marker portion having a predetermined positioning shape; and
a connection portion connecting the marker portion and the outer edge of the base material.

6. The display panel according to claim 5, wherein the connection portion has,
in plan view, a shape that gradually widens from the marker portion toward the outer edge of the base material.

7. The display panel according to claim 1, wherein the adhesive layer is a double-sided tape having a light-transmissive property.

8. The display panel according to claim 1, wherein the light-transmissive printed layer is a white printed layer formed by silk screen printing.

9. The display panel according to claim 1, wherein the light-shielding printed layer is a black printed layer formed by silk screen printing.
